(19) United States
(12) Patent Application Publication
(10) Pub. No.: US 2010/0149410 A1
(43) Pub. Date: Jun. 17, 2010

(54) ELECTRONIC COMPONENT APPARATUS

(75) Inventor: Satoshi MATSUZAWA, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/635,038

(22) Filed: Dec. 10, 2009

(30) Foreign Application Priority Data
Dec. 11, 2008 (JP) 2008-315909

(51) Int. Cl. H04N 5/225; H05K 1/16

(52) U.S. Cl. 348/374; 174/260; 348/E05.024

(57) ABSTRACT

An electronic component apparatus includes a wiring board 10, an electronic component 20 disposed thereon, a frame-like member 30 provided on the wiring board 10 to surround the electronic component 20 and to have a ring-like bonding portion 34, and a cap member 50 which is bonded to the ring-like bonding portion 34 of the frame-like member 30 to constitute a housing portion H for housing the electronic component 20 together with the wiring board 10 and the frame-like member 30. In an upper part of one region of the ring-like bonding portion 34, a groove 36 for air contained in the housing portion H is provided to extend from an inner peripheral surface of the ring-like bonding portion 34 to an outer side of the cap member 50.

### CROSS-REFERENCE TO RELATED APPLICATION

This application is based on and claims priority under 35 U.S.C. §119 from Japanese Patent Application No. 2008-315909 filed on Dec. 11, 2008.

### BACKGROUND OF THE INVENTION

1. Technical Field

The present invention relates to an electronic component apparatus and, more particularly, to an electronic component apparatus suitably applicable to a camera module or the like.

2. Related Art

Hitherto, a camera module for constituting a camera portion of a portable terminal or the like has been developed.

JP-A-2007-194930 describes a solid-state image pickup apparatus configured so that this apparatus has a structure in which a solid-state image element and a transparent member are mounted, that the structure has a solid-state image element mounting portion provided with a through-opening part, and has also a step portion provided at an edge part of the through-opening part, on which the transparent member is mounted, and that a light receiving surface of the solid-state image element and the transparent member are mounted at a predetermined distance from each other to close the through-opening part.

JP-A-2008-11144 describes an image pickup apparatus configured so that a vent hole is formed into a wide-width shape to prevent dust from infiltrating into a space between an optical filter and an image pickup element arranged across an opening portion formed in a solid board, and that a part extending from a flat portion to an opening end of a wide portion of the vent hole is formed into a tapered shape thereby smoothly sealing the vent hole with an adhesive agent.

As described below in the description of related art, a process of assembling a camera module includes a step of bonding a glass cap by a thermoset adhesive agent to a frame-like member arranged to surround an image pickup element mounted on a board. The related art has a problem in that in this step, when the adhesive agent is hardened by being heat-treated, air contained in a space is expanded by heat so as to upwardly press the glass cap, so that the glass cap is not well bonded to the frame-like member.

One countermeasure against this problem is a method of providing an adhesive-unapplied area on the frame-like member without applying an adhesive agent on a part thereof to externally discharge expanded air from a gap formed between the glass gap and the frame-like member,

However, when the surfaces of the frame-like member and the glass cap are sufficiently smooth, the gap therebetween is too small, so that the expanded air cannot sufficiently be discharged. On the other hand, when irregularities are formed on the surfaces of the frame-like member and the glass cap, the gap-width is increased, though the expanded air can be discharged. Thus, there is a fear of infiltration of foreign substances into the space.

### SUMMARY OF THE INVENTION

The invention is created in view of the above problem. An object of the invention is to provide an electronic component apparatus capable of bonding a cap member to a frame-like member without occurrence of troubles.

According to a first aspect of the invention, there is provided an electronic component apparatus, including:

a wiring board;

an electronic component disposed on the wiring board;

a frame-like member that is provided on the wiring board to surround the electronic component and that has a ring-like bonding portion; and

a cap member bonded to the ring-like bonding portion of the frame-like member to constitute a housing portion for housing the electronic component, together with the wiring board and the frame-like member, wherein

in an upper part of one region of the ring-like bonding portion, one or more grooves for discharging air contained in the housing portion are provided to extend from an inner peripheral surface of the ring-like bonding portion to an outer side of the cap member.

According to a second aspect of the invention, there is provided the electronic component apparatus according to the first aspect, wherein

the groove has a bent portion.

According to a third aspect of the invention, there is provided the electronic component apparatus according to the first aspect, wherein

the cap member is bonded to the ring-like bonding portion by a thermoset adhesive agent formed on a region other than at least a part of the groove region in which the one or more grooves are provided.

According to a forth aspect of the invention, there is provided the electronic component apparatus according to any one of the first to third aspects, wherein

the number of the grooves provided in the groove region is equal to or more than three.

According to a fifth aspect of the invention, there is provided the electronic component apparatus according to any one of the first to third aspects, wherein

the frame-like member includes a frame portion and the ring-like bonding portion that protrudes inwardly from an inner peripheral surface of the frame portion; and

the grooves are formed to extend from an inner peripheral surface of the ring-like bonding portion to an inner peripheral surface of the frame portion.

According to a sixth aspect of the invention, there is provided the electronic component apparatus according to any one of the first to third aspects, further including:

a lens module arranged on the frame-like member and the cap member, wherein

the electronic component apparatus is a camera module;

the electronic component is an image pickup element;

the cap member is formed of glass.

According to a seventh aspect of the invention, there is provided the electronic component apparatus according to the first to third aspects, wherein

the electronic component is an optical semiconductor element or an MEMS element.

In an electronic component apparatus having a structure in which an electronic component is housed in a housing portion, a frame-like member is fixed onto a wiring board on which an electronic component is disposed. A cap member is bonded to a ring-like bonding portion of the frame-like member. For example, in a camera module, an image pickup element is used as the electronic component. A transparent glass cap is used as the cap member.

At that time, as described above, there is a problem that when the cap member is bonded thereto by heating the thermoset adhesive agent to harden the adhesive agent, air expanded by heating the inside of the housing portion is not well discharged, so that the cap member cannot reliably be bonded thereto.

According to the invention, a groove for exteriorly discharging air contained in the housing portion is provided to extend from the inner peripheral surface of an upper part of a region of the ring-like bonding portion of the frame-like member to the outside of the cap member. Consequently, the invention can surely assure an appropriate groove for discharging, when the cap member is disposed on the frame-like member of the ring-like bonding portion, air expanded in the housing portion regardless of the surface state (smoothness) of each of the frame-like member and the cap member.

Accordingly, the cap member can reliably be bonded to the ring-like bonding portion of the frame-like member without being affected by the air expanded in the housing portion.

When the groove is formed into a straight shape, there is a fear that a foreign substance having a width smaller than that of the groove may filtrate into the housing portion. The infiltration of a foreign substance into the housing portion can be prevented by bending the groove. Thus, a foreign substance becomes difficult to adhere to the electronic component, so that the reliability thereof can be enhanced.

In a preferred embodiment of the invention, a target foreign substance can surely be eliminated by adjusting the widths, the number, and the pitch of the grooves, and the number of the bent portions according to the performance specifications of various electronic component apparatuses. Consequently, the manufacturing yields of various electronic component apparatuses can be improved.

As described above, according to the invention, the cap member can be bonded to the frame-like member without occurrence of a trouble.

### BRIEF DESCRIPTION OF THE DRAWINGS

FIG. 1 is a cross-sectional view illustrating a method of mounting a glass cap in a related cameral module.

FIG. 2 is a plan view illustrating the method of mounting a glass cap in the related cameral module.

FIG. 3 is a cross-sectional view (#1) illustrating problems of the method of mounting a glass cap in the related cameral module.

FIG. 4 is a cross-sectional view (#2) illustrating the problems of the method of mounting a glass cap in the related cameral module.

FIGS. 5A to 5C are cross-sectional views (#1) illustrating a manufacturing method for a camera module (electronic component) according to a first embodiment of the invention.

FIG. 6A is a plan view, taken from above, illustrating a structure illustrated in FIG. 5B. FIG. 6B is a cross-sectional view taken along line I-I illustrated in FIG. 6A.

FIG. 7 is a plan view illustrating a condition in which an adhesive agent is applied to a ring-like bonding portion of a frame-like member according to the manufacturing method for a camera module (electronic component) according to the first embodiment of the invention.

FIG. 8 is a plan view illustrating a condition in which a glass cap is bonded to the ring-like bonding portion of the frame-like member according to the manufacturing method for a camera module (electronic component) according to the first embodiment of the invention.

FIG. 9 is a cross-sectional view taken along line II-II illustrated in FIG. 8.

FIG. 10 is a cross-sectional view schematically illustrating a cross-sectional part along the inside of a groove, which is taken along line shown in FIG. 8.

FIGS. 11A and 11B are cross-sectional views illustrating another manufacturing method for a camera module (electronic component apparatus) according to the first embodiment of the invention.

FIG. 12 is a cross-sectional view illustrating a camera module (electronic component apparatus) according to the first embodiment of the invention.

FIG. 13 is a cross-sectional view illustrating an optical semiconductor apparatus (electronic component apparatus) according to a second embodiment of the invention.

FIG. 14 is a cross-sectional view illustrating an optical semiconductor apparatus (electronic component apparatus) according to a modification of the second embodiment of the invention.

FIGS. 15A to 15C are cross-sectional views illustrating a MEMS apparatus (electronic component apparatus) according to a third embodiment of the invention.

### DETAILED DESCRIPTION OF THE PREFERRED EMBODIMENTS

Hereinafter, embodiments of the invention are described with reference to the accompanying drawings.

### (Related Art)

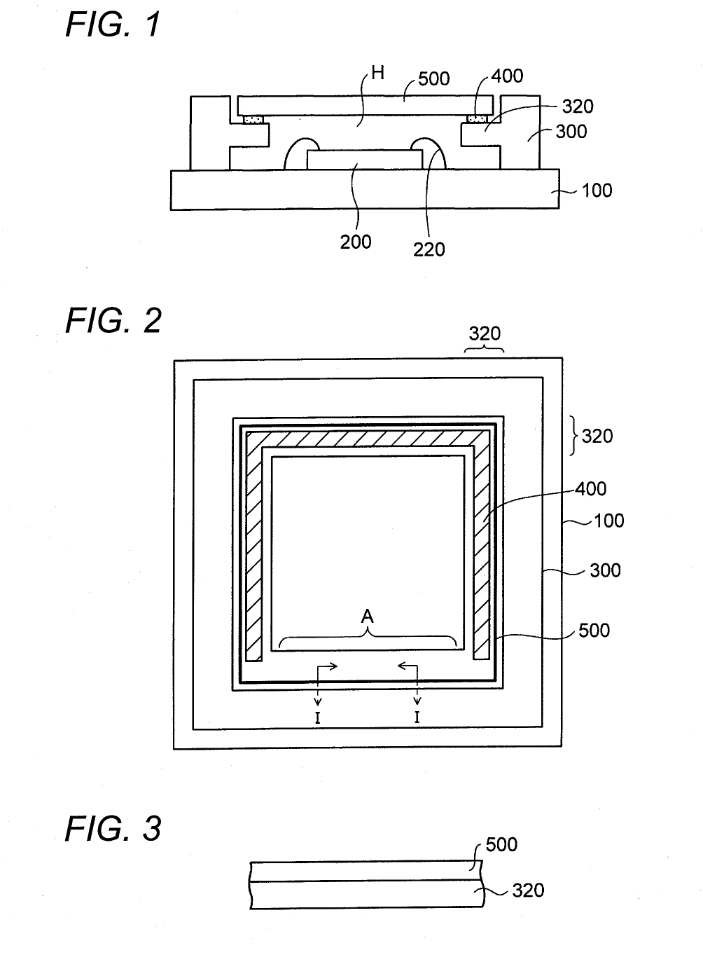

Before the embodiments of the invention are described, problems according to related art relating to the invention are described below. FIGS. 1 and 2 are a cross-sectional view and a plan view illustrating a method of mounting a glass cap in a related camera module, respectively.

As illustrated in FIG. 1, an image pickup element 200 is mounted on a wiring board 100 having a wiring layer (not shown). The image pickup element 200 is fixed onto the wiring board 100 such that a light receiving surface of the image pickup element 200 is faced up. A connection pad (not shown) of the image pickup element 200 is connected to a wiring layer of the wiring board 100 via a wire 220.

A frame-like member 300 is fixed onto the wiring board 100 to surround the image pickup element 200. The frame-like member 300 has a ring-like bonding portion 320 provided on the inner peripheral surface so as to protrude inwardly.

A glass cap 500 is bonded onto the ring-like bonding portion 320 of the frame-like member 300 with an adhesive agent 400. Thus, the image pickup element 200 is housed in a housing portion H including the wiring board 100, the frame-like member 300, and the glass cap 500.

The glass cap 500 is bonded to the ring-like bonding portion 320 of the frame-like member 300 by heating the thermoset adhesive agent 400 at 85° C. to harden the adhesive agent 400. At that time, the housing portion H is in a hermetically-sealed state. Thus, there is a problem that the glass cap 500 is upwardly pushed by the expanded air and that consequently, the glass cap 500 is not well bonded to the frame-like member.

One countermeasure against this problem is a method of providing an adhesive-unapplied area A in one rectangular region of the ring-like bonding portion 320 of the frame-like member 300 as illustrated in a plan view shown in FIG. 2. FIG. 2 omits the drawing of the image pickup element 200. Consequently, the adhesive unapplied area A is in a state in which the ring-like bonding portion 320 of the frame-like member 300 is simply contacted with the glass cap 500. Thus, the expanded air can be discharged from the gap between the adhesive unapplied area A and the glass cap 500 to the outside.

However, variation in the surface state (smoothness) of each of the ring-like bonding portion 320 of the frame-like member 300 and the glass cap 500 is caused every time the adhesive unapplied area A is provided. Thus, it is difficult to stably obtain an appropriate gap between the adhesive unapplied area A and the glass cap 500.

That is, as illustrated in FIG. 3 (which is a cross-sectional view taken along line I-I shown in FIG. 2), when the degree of the smoothness of the surface of each of the ring-like bonding portion 320 and the glass cap 500 is high, both the ring-like bonding portion 320 and the glass cap 500 are contacted with each other substantially without a gap. Thus, the expanded air cannot be discharged to the outside.

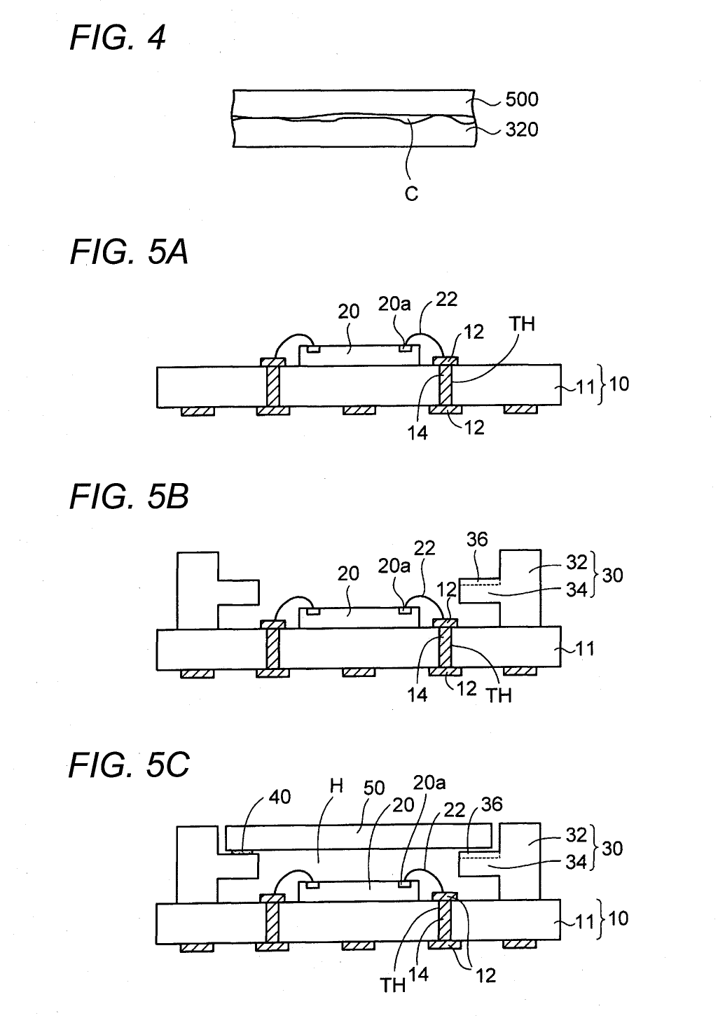

On the contrary, as illustrated in FIG. 4 (which is a cross-sectional view taken along line I-I shown in FIG. 2), when the degree of the smoothness of the surface of each of the ring-like bonding portion 320 and the glass cap 500 is low, the adhesive unapplied area A is set to be relatively large. Thus, sometimes, a gap C larger than needed is provided according to the combination of irregularities of both of the ring-like bonding portion 320 and the glass cap 500.

When the large gap C is caused, a foreign substance (such as dust in the air) can easily filtrate into the housing portion H from the cap C, though the expanded air can be discharged to the outside. Consequently, a foreign substance adheres onto the image pickup element 200. Thus, reduction in the reliability of the image pickup element 200 is caused.

As described above, according to the related art, it is extremely difficult to stably construct an appropriate gap, from which the expanded air can easily be discharged and into which a foreign substance is hard to infiltrate, between the ring-like bonding portion 320 of the frame-like member 300 and the glass cap 500.

Embodiments described hereinafter can solve defects of the above related art.

### First Embodiment

FIGS. 5A to 5C are cross-sectional views illustrating a method of manufacturing a camera module according to a first embodiment of the invention, and FIGS. 11A and 11B are plan views illustrating this method. In the following description of the present embodiment, a camera module serving as an electronic component apparatus is described by way of example.

First, a wiring board 10 illustrated in FIG. 5A is prepared. A through-hole TH penetrating through an insulating substrate 11 made of a glass epoxy resin in the thickness direction of the wiring board 10. The through-hole TH is filled with a through-electrode 14. Wiring layers 12 are formed on each of both sides of the insulating substrate 12. The wiring layers 12 respectively formed on both sides of the insulating substrate 11 are connected via the through-electrode 14 to each other. It is sufficient that the wiring board 10 has a wiring layer. Core substrates made of various materials can be employed as the wiring board 10.

Then, an image pickup element (electronic component) 20 is mounted on the wiring board 10 in a state in which the light receiving surface of the image pickup element 20 is faced up. A complementary metal-oxide semiconductor (CMOS) image sensor and a charge-coupled device (CCD) are used as the image pickup element 20. Each connection pad 20a of the image pickup element 20 is connected to the associated wiring layer 12 of the wiring board 10 by a wire 22.

Next, as illustrated in FIG. 5B, the frame-like member 30 is fixed onto the wiring board 10 to surround the image pickup element 20. The frame-like member 30 includes a frame portion 32 and a ring-like bonding portion 34 that projects inwardly from a central portion of the inner peripheral surface of the frame portion 32. As will be described below, the glass cap is bonded onto the top surface of the ring-like bonding portion 34.

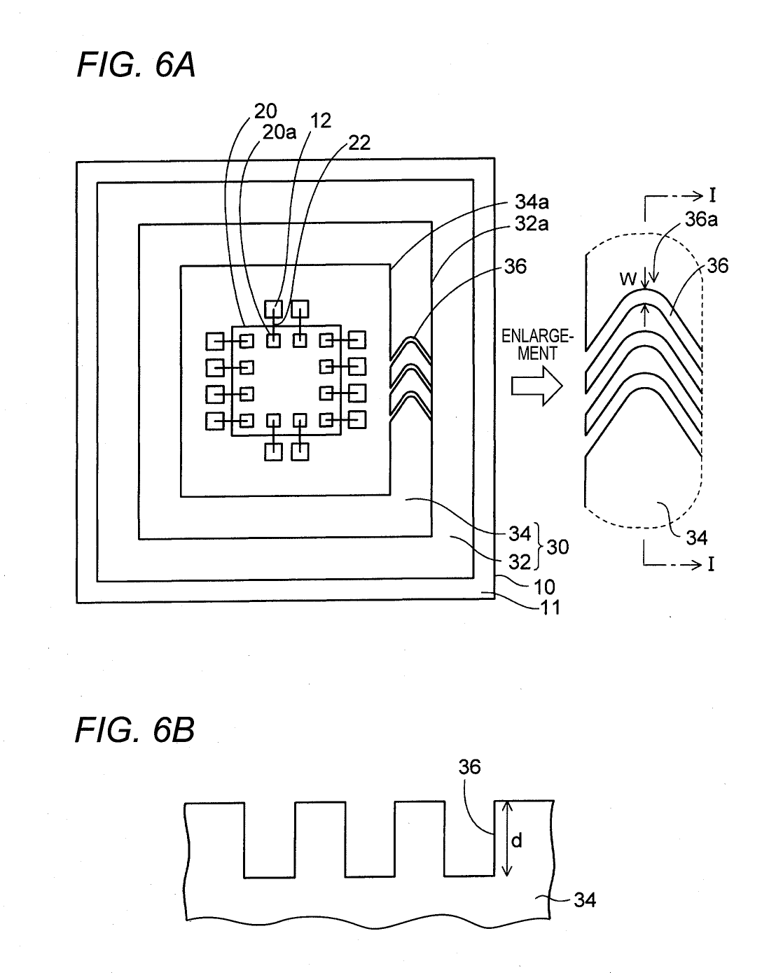

FIG. 6A shows a plan view, taken from above, illustrating a structure shown in FIG. 5B. As illustrated in FIG. 6A, the ring-like bonding portion 34 of the frame-like member 30 is provided integrally with the frame portion 32 as a rectangular ring portion. Three grooves 36 are provided side by side in a central portion of one (right-side one, as viewed in FIG. 6A) of four rectangular regions of the ring-like bonding portion 34.

Each groove 36 is provided to extend from an inner peripheral surface 34a of the ring-like bonding portion 34 to an inner peripheral surface 32a of the frame portion 32. Each groove 36 has one bent portion 36a at a central portion in a width direction thereof. As illustrated in FIG. 6B (which is a partial cross-sectional view taken along line I-I shown in FIG. 6A), each groove 36 is formed on a part extending from the top surface of the ring-like bonding portion 34 to a place that corresponds to a part of a thickness thereof.

As will be described below, the grooves 36 provided in the ring-like bonding portion 34 of the frame-like member 30 are utilized as paths for discharging the air expanded by heat to the outside when a thermoset adhesive agent is heated to bond the glass cap to the ring-like bonding portion 34.

The bent portions 36a of the grooves 36 are provided to prevent a foreign substance (such as dust in the air) from infiltrating into the space. In an example illustrated in FIGS. 6A and 6B, each groove 36 includes one bent portion 36a. However, the number of the bent portions can optionally be set. The larger the number of the bent portions 36a becomes, the more an effect in preventing a foreign substance from filtrating into the space becomes profound.

Or, when the filtration of a foreign substance into the space does not matter, each groove 36 can be formed to extend in a straight shape. Even when the groove 36 is formed in a straight shape, the infiltration of a foreign substance having a diameter larger than that of each groove 36 thereinto can be prevented by reducing the width of each groove 36.

Although the configuration of arranging the three grooves 36 side by side has been exemplified, the number and the pitch of the grooves 36 can optionally be set.

For example, when the image pickup element 20 to be used in a camera module of a portable telephone is mounted, the width w of each groove 36 (see a partially enlarged view illustrated in FIG. 6A) is about 100 μm. The depth d of each groove 36 (see FIG. 6B) is set at about 50 μm.

The frame-like member 30 provided with the grooves 36 in the ring-like bonding portion 34 can be obtained by performing collective molding, i.e., a process of casting a resin, such as polycarbonate (PC), into a mold, then rapidly cooling and solidifying the resin, and finally taking the resin out of the mold.

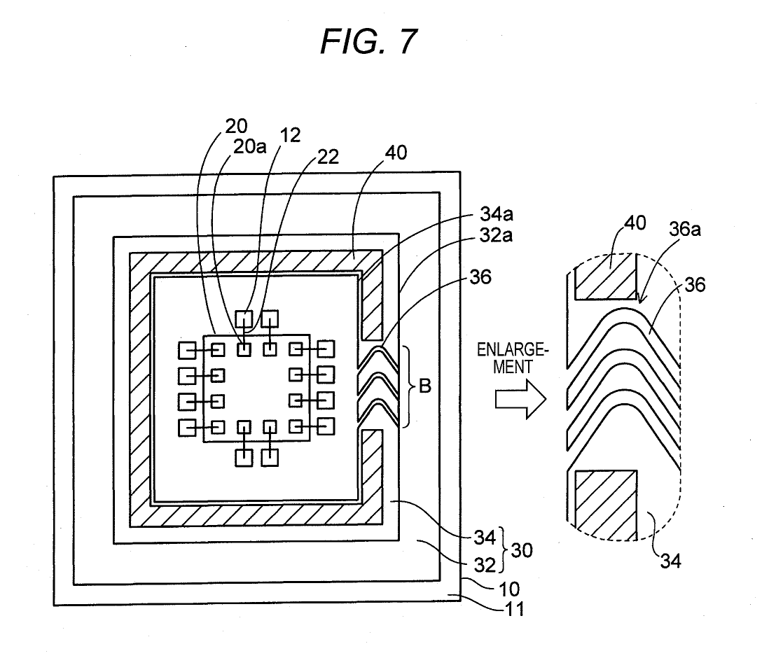

Next, as illustrated in FIG. 7, a thermoset adhesive agent (slash-hatched portion) 40 is applied onto the top surface of the ring-like bonding portion 34 of the frame-like member 30. At that time, the adhesive agent 40 is selectively applied onto a region of the top surface of the ring-like bonding portion 34, which is other than a groove region B in which the grooves 36 are arranged. An epoxide-based adhesive agent or a urethane-based adhesive agent is used as the thermoset adhesive agent 40.

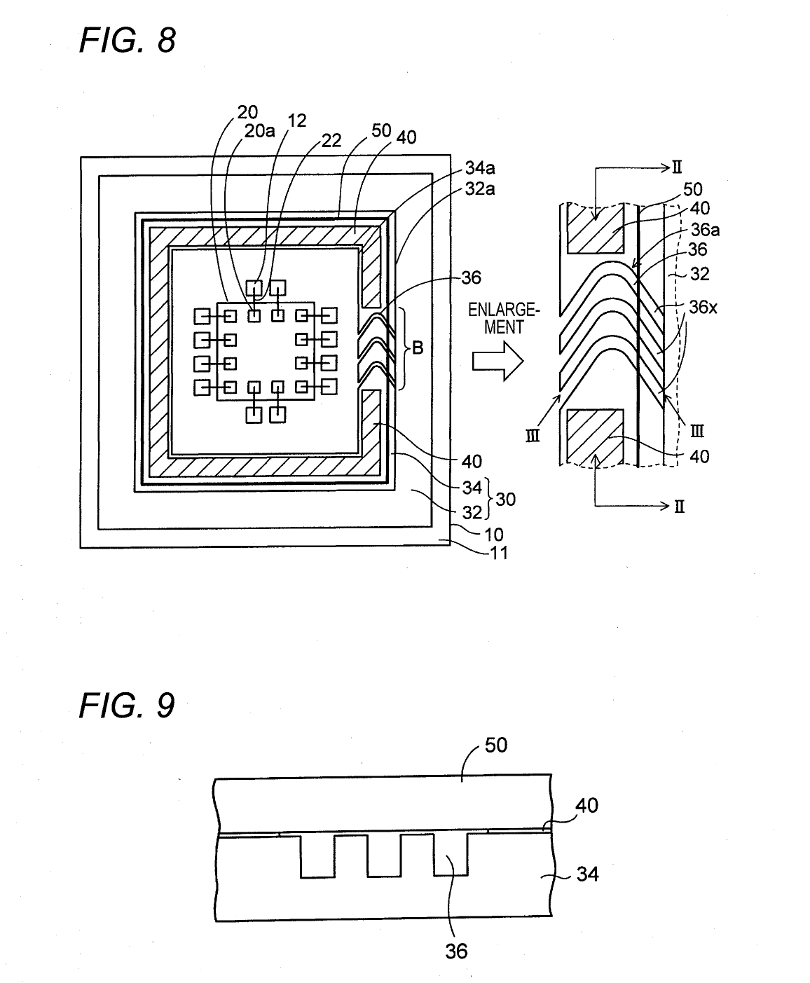

Next, as illustrated in FIGS. 5C and 8, a transparent glass cap 50 is prepared, which is one size smaller than the outer shape of the ring-like bonding portion 34 of the frame-like member 30. The glass cap 50 (indicated by a thick frame shown in FIG. 8) is disposed on the ring-like bonding portion 34. The glass cap 50 functions as an infrared (IR) cut filter, which eliminates light having a wavelength that is within an IR range, other than visible light from outside light.

Additionally, the thermoset adhesive agent 40 is hardened by being heat-treated at about 85° C. Thus, the glass cap 50 is bonded to the ring-like bonding portion 34 of the frame-like member 30. Consequently, the image pickup element 20 is housed in the housing portion H that includes the wiring board 10, the frame-like member 30, and the glass cap 50, as illustrated in FIG. 5C.

At that time, the grooves 36 formed in an upper portion of the frame-like member 30 are arranged to extend from the inner peripheral surface 34a of the ring-like bonding portion 34 of the frame-like member 30 to an outer side of the glass cap 50.

FIG. 9 illustrates a partially cross-sectional view taken along line II-II shown in FIG. 8. At that time, as illustrated in FIGS. 8 and 9, the adhesive agent 40 is not applied to the groove region B of the ring-like bonding portion 34 of the frame-like member 30. Thus, the grooves 36 under the glass cap 50 are left as cavities.

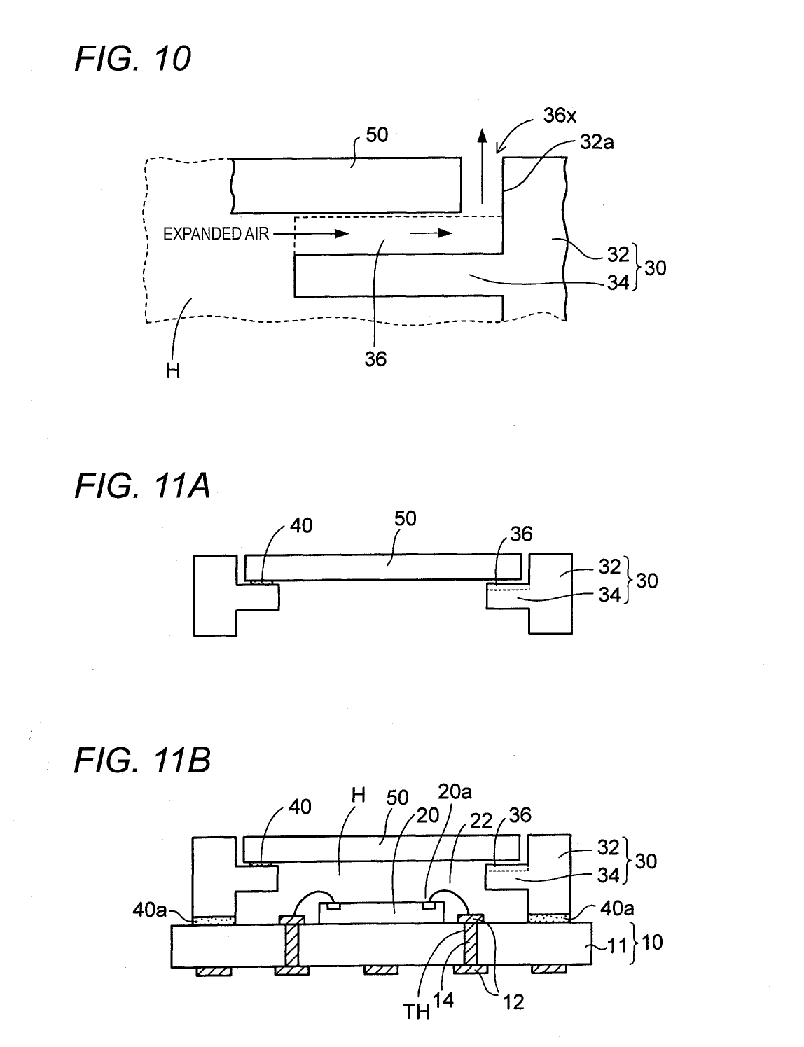

FIG. 10 shows a cross-sectional view schematically illustrating a cross-sectional part along each groove 36, which is taken along line shown in FIG. 8. As illustrated in FIG. 10, the air contained in the housing portion H, which is expanded by heat treatment performed when the adhesive agent 40 is hardened, passes through the grooves 36 provided in the ring-like bonding portion 34 and is discharged from an upper portion 36x (see an enlarged view shown in FIG. 8 simultaneously) of each groove 36 provided between the glass cap 50 and the inner peripheral surface 32a of the frame portion 32.

Consequently, even in a case where the air contained in the housing portion H is expanded when the adhesive agent 40 is hardened, the expanded air is easily discharged to the outside via the grooves 36. Thus, there is no fear that the glass cap 50 is upwardly pressed. Consequently, the glass cap 50 is reliably bonded to the ring-like bonding portion 34.

The widths w, the number, the depths d and the pitch of the grooves 36 provided in the ring-like bonding portion 34, and the number of the bent portions 36a can appropriately be adjusted according to the performance specification of the electronic component apparatus. That is, because the size of a foreign substance to be blocked varies with the performance of the image pickup element 20 and the like, it is useful that the width w of each groove 36 and the number of the bent portions 36a and the like are adjusted to prevent a foreign substance from entering the housing portion H.

Even when a foreign substance externally filtrates into the groove 36, the foreign substance is stopped by the bent portions 36a. Thus, the foreign substance can be prevented from entering the housing portion H. The larger the number of the bent portions 36a of the grooves 36 becomes, the more the effect in preventing a foreign substance from filtrating into the space becomes profound.

Thus, the grooves 36 are provided in one region of the ring-like bonding portion 34 of the frame-like member 30. Consequently, when the glass cap 50 is bonded to the ring-like bonding portion 34 by heat-treating the adhesive agent 40, the air expanded in the housing H can stably be discharged to the outside. In addition, a foreign substance can be prevented from infiltrating into the space.

According to the present embodiment, it is preferable that the groove region B, in which the grooves 36 of the ring-like bonding portion 34 are arranged, is set to be as small as possible, and that the adhesive agent 40 is provided in as many regions of the ring-like bonding portion 34 as possible.

As described in the foregoing description of the related art, the surface state (smoothness) of each of the ring-like bonding portion 34 of the frame member 30 and the glass cap 50 varies every time the ring-like bonding portion 34 and the glass cap 50 are bonded to each other. Thus, when the groove region B is fairly large, sometimes, concave parts of both the ring-like bonding portion 34 and the glass cap 50 accidentally overlap with each other. There is a fear that an unnecessarily large gap may be generated between the groove region B and the glass cap 50.

However, the possibility of arranging a large gap between the groove region B and the glass cap 50 can considerably be reduced by setting the groove region B of the ring-like bonding portion 34 to be as small as possible.

According to the present embodiment, preferably, three or more grooves 36 are arranged side by side. When the groove region B is set to be as small as possible, as described above, it is necessary to apply the adhesive agent 40 to the vicinity of the grooves 36. At that time, even in a case where the adhesive agent 40 flows into outer two of the grooves 36 among the three grooves 36 and where the two grooves 36 are filled with the adhesive agent 40, at least the central grove 36 can be left as a cavity.

Thus, according to the present embodiment, even when the surface state (smoothness) of each of the frame-like member 30 and the glass cap 50 varies, the grooves 36 serving as paths for discharging expanded air can surely be assured. Consequently, the present embodiment excels in mass productivity. The yield thereof can be enhanced.

According to a method of manufacturing the above electronic component, as illustrated in FIGS. 5A to 5C, the glass cap 50 is bonded to the ring-like bonding portion 34 of the frame-like member 30 after the frame-like member 30 is fixed onto the wiring board 10 on which the image pickup element 20 is mounted.

Another manufacturing method which will be described below can be used as a modification. That is, as illustrated in FIG. 11A, first, the glass cap 50 is bonded to the ring-like bonding portion 34 of the frame-like member 30 by the adhesive agent 40 before the frame-like member 30 is fixed to the wiring board 10.

Subsequently, as illustrated in FIG. 11B, the bottom surface of the frame-like member 30 to which the glass cap 50 is bonded is bonded onto the wiring board 10, on which the image pickup element 20 is mounted, by the adhesive agent 40a. At that time, similarly, even in a case where air contained in the housing portion H is expanded when the adhesive agent 40a is hardened by being heat-treated, the expanded air is easily discharged to the outside via the grooves 36.

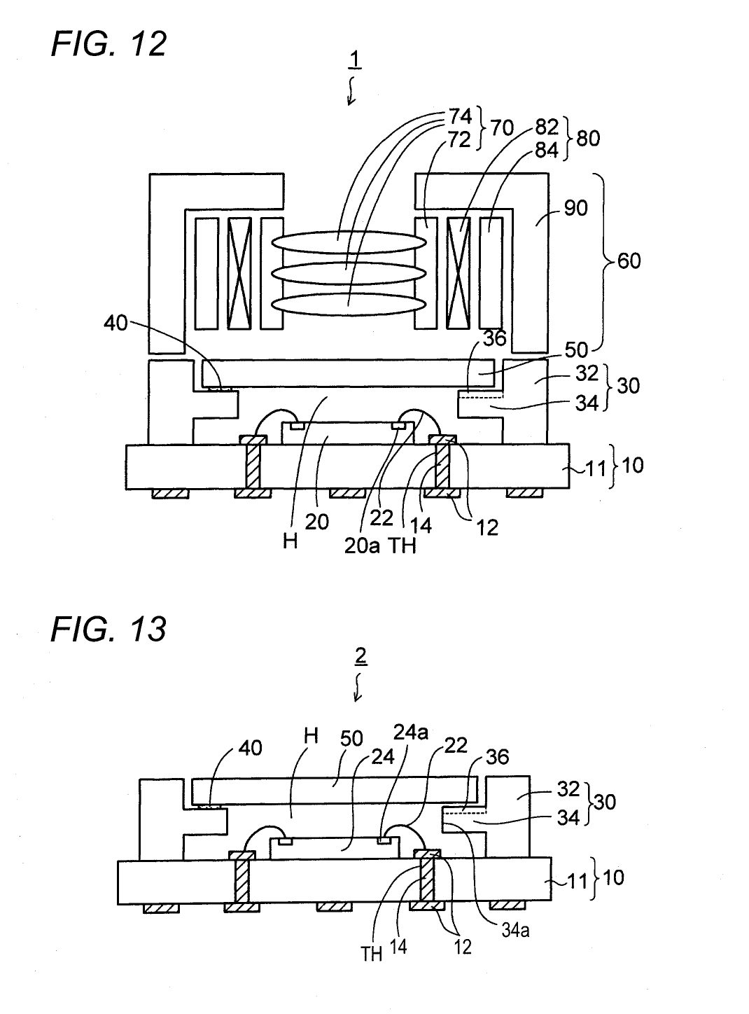

Next, as illustrated in FIG. 12, a lens unit 60 is provided over the frame-like member 30 and the glass cap 50 illustrated in FIG. 5C. The lens unit 60 basically includes a lens portion 70, a voice coil motor (VCM) 80 serving as an actuator for driving the lens portion 70, and an outer frame portion 90 that supports these composing-elements.

The lens portion 70 includes a cylindrical holding body 72, and a lens group 74 having a plurality of lenses aligned perpendicularly to the wiring board, which are held in the cylindrical holding body 72.

The VCM 80 for driving the lens portion 70 in the direction of an optical axis (up-down direction, as viewed in FIG. 12) is provided on an outer peripheral side of the lens portion 70. The VCM 80 includes a coil 82 wound around the outer periphery of the cylindrical holding body 72 of the lens portion 70, and a magnet 84 arranged on the outer peripheral side of the coil 82.

The lens portion 70 can be driven by feeding a predetermined current through the coil 82 so as to receive a thrust force in the direction of the optical axis based on the principle of what is called a linear motor. That is, the lens portion 70 is driven anteroposteriorly by a function of the VCM 80. Thus, focusing of an image is controlled. A spring (not shown) is attached to the lens portion 70. Consequently, the lens portion 70 can be returned to a normal position by the spring.

Thus, the camera module (electronic component apparatus) 1 according to the first embodiment is obtained.

As described above, the camera module 1 according to the first embodiment includes the grooves 36 for discharging the expanded air, which are provided in the ring-like bonding portion 34 of the frame-like member 30. Thus, the glass cap 50 can reliably be bonded to the ring-like bonding portion 34 by the adhesive agent 40.

### Second Embodiment

FIG. 13 is a cross-sectional view illustrating an optical semiconductor apparatus (electronic component apparatus) 2 according to a second embodiment of the invention. A feature of the second embodiment resides in that the invention is applied to the assembly of an optical semiconductor apparatus. In the following description of the second embodiment, the description of the same process and the same composing-element as those of the first embodiment is omitted.

In the second embodiment, as illustrated in FIG. 13, an optical semiconductor element (electronic component) 24 is mounted on the same wiring board 10 as that illustrated in FIG. 5A. A surface emitting semiconductor laser or a surface receiving element (such as a photodiode) is used as the optical semiconductor element 24. The optical semiconductor element 24 is mounted on the wiring board 10 so that a light emitting surface (or a light receiving surface) is faced up. In addition, each connection pad 24a of the optical semiconductor element 24 is electrically connected to a wiring layer 12 of the wiring board 10 by the wire 22.

Similarly to the first embodiment, the frame-like member 30 having the ring-like bonding portion 34 provided with grooves 36 is fixed onto the wiring board 10. Additionally, similarly to the first embodiment, the glass cap 50 is bonded onto the ring-like bonding portion 34 of the frame-like member 30 by the thermoset adhesive agent 40. Similarly, in the second embodiment, the grooves 36 formed in an upper part of the ring-like bonding portion 34 are arranged to extend from an inner peripheral surface 34a of the ring-like bonding portion 34 to an outer side of the glass cap 50.

Similarly to the first embodiment, in the optical semiconductor apparatus 2 illustrated in FIG. 13, air expanded in the housing portion H is discharged from the grooves 36 to the outside when the glass cap 50 is bonded to the ring-like bonding portion 34 by the thermoset adhesive agent 40. Thus, the glass cap 50 is stably bonded thereto.

The optical semiconductor apparatus 2 is used as a light receiving device or a light emitting device for optical communication.

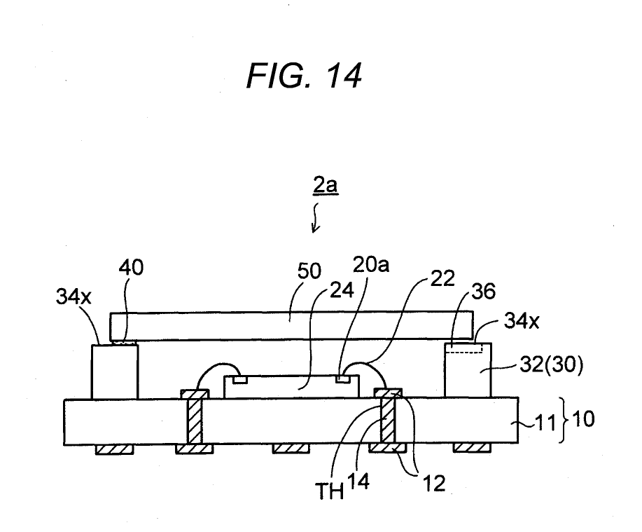

FIG. 14 illustrates an optical semiconductor apparatus (electronic component apparatus) 2a which is a modification of the second embodiment. As illustrated in FIG. 14, the frame-like member 30 can be configured to include only the frame portion 32 by omitting the ring-like bonding portion 34 which inwardly protrudes as illustrated in FIG. 13, so that the top surface of the frame-like member 30 can be used as the ring-like bonding portion 34x.

Similarly, the grooves 36 are provided in one region of the ring-like bonding portion 34x. The glass cap 50 is bonded to the ring-like bonding portion 43a of the frame-like member 30 by the thermoset adhesive agent 40.

In the optical semiconductor apparatus 2a according to the modification illustrated in FIG. 14, the grooves 36 can be formed to extend from the inner peripheral surface of the frame-like member 30 to the outer peripheral surface thereof.

In FIG. 14, composing-elements other than the frame-like member 30 are the same as those illustrated in FIG. 13 and designated with the same reference numerals as used in FIG. 13. Thus, the description of such composing-elements is omitted.

### Third Embodiment

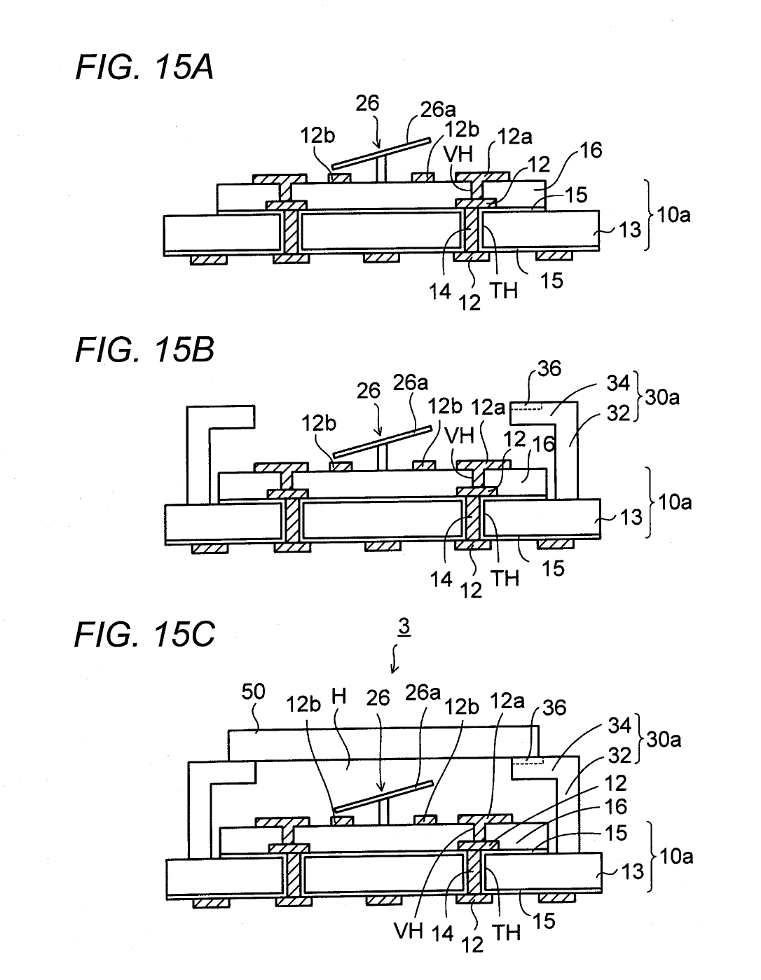

FIGS. 15A to 15C are cross-sectional views illustrating a method for manufacturing a micro-electro-mechanical system (MEMS) apparatus (electronic component apparatus) according to a third embodiment of the invention. A feature of the third embodiment resides in that the invention is applied to the assembly of an MEMS apparatus.

According to the third embodiment, first, a wiring board 10a is prepared, on which a switch element (MEMS element) 26 illustrated in FIG. 15A is arranged. In the wiring board 10a, through-holes TH are provided in a silicon substrate 13. An insulating layer 15 containing a silicon dioxide layer is formed on the top surface and the bottom surface of the silicon substrate 13 and in the through-hole TH. In addition, a through-electrode 14 is provided in each through-hole TH. First wiring layers 12 connected to each other via each through-electrode 14 are formed on both surface sides of the silicon substrate 13, respectively.

A protection layer 16 for coating over the first wiring layer 12 is formed on the silicon substrate 13. A via-hole VH reaching the first wiring layer 12 is formed in the protection layer 16. A second wiring layer 12a connected to the first wiring layer 12 via the vial-hole VH is formed on the protection layer 16.

A switching element 26 having a movable portion (cantilever) 26a with a supporting point is formed on the protection layer 16 as the MEMS element. Electrodes 12b are provided on the protection layers 16 respectively corresponding to both end parts of the movable portion 26a of the switching element 26.

The switching element 26 is configured so that driving energy is supplied to the movable portion 26a made of a magnetic alloy by the action of a planar coil (not shown) provided in the protection layer 16, and that when the movable portion 26a is inclined and contacted with the electrode 12b, the switching circuit is turned on.

Although the switching element 26 has been exemplified as the MEMS element (electronic component), an accelerator or a display element including many micro-mirrors arranged on a plane can be mounted as the MEMS element.

As illustrated in FIG. 15B, a frame-like silicon member 30a including a frame portion 32 and a ring-like bonding portion 34 is fixed onto the silicon substrate 13. As illustrated in FIG. 15B, the ring-like bonding portion 34 can be provided at an upper part of the inner peripheral surface of the frame portion 32. Similarly to the first embodiment, the grooves 36 are provided in one region of the ring-like bonding portion 34 of the frame-like silicon member 30a.

Even in the third embodiment, the grooves 36 formed in an upper part of the ring-like bonding portion 34 are arranged to extend from the inner peripheral surface of the ring-like bonding portion 34 to an outer side of the glass cap 50. Alternatively, the grooves 36 can be formed to extend from the inner peripheral surface of the ring-like bonding portion 34 to an outer peripheral surface of the frame-like silicon member 30a.

In order to obtain such a frame-like silicon member 30a, it is useful to perform the following process. That is, first, the grooves 36 are formed in a predetermined part of one of surfaces of a silicon wafer by reactive ion etching (RIE) or the like. Then, a concave portion extending from the other surface of the silicon wafer to a place that corresponds to a part of a thickness thereof is formed by RIE or the like. Additionally, penetration processing is performed on the center of the bottom part of the concave portion by RIE or the like. Subsequently, the silicon wafer is cut.

Next, as illustrated in FIG. 15C, the transparent glass cap 50 is bonded onto the ring-like bonding portion 34 of the frame-like silicon member 30a by anodic bonding. Conditions for performing anodic bonding are, e.g., that a voltage of 500V to 1 KV is applied between the frame-like silicon member 30a and the glass cap 50 while the frame-like silicon member 30a and the glass cap 50 are heated at temperature of 300° C. to 400° C. in a state in which the glass cap 50 is disposed on the frame-like silicon member 30a.

Consequently, a large electrostatic attractive force is generated between the frame-like silicon member 30a and the glass cap 50. Then, chemical bonding occurs at the interface therebetween. Consequently, the glass cap 50 is bonded to the ring-like bonding portion 34. Thus, the switching element 26 is housed in the housing portion H that includes the wiring board 10a, the frame-like silicon member 30a, and the glass cap 50.

Even when the glass cap 50 is bonded to the frame-like silicon member 30a by anodic bonding, air contained in the housing portion H, which is expanded by being heated, is discharged from the grooves 36 to the outside. Consequently, the glass cap 50 can stably be bonded thereto.

Accordingly, the MEMS apparatus (electronic component apparatus) 3 according to the third embodiment is obtained.

When the MEMS element is mounted on the wiring board, it is not always necessary to use the transparent glass cap. Cap members made of various opaque materials can be used according to the use thereof. When anodic bonding is not used (the materials of the frame-like member and the cap member are other than the combination of silicon and glass), the cap member is bonded to the frame-like member by the thermoset adhesive agent, similarly to the first embodiment.

As described above, the invention can be applied to the electronic component apparatus having a structure in which the cap member is bonded to the frame-like member based on the bonding using the thermoset adhesive agent or utilizing heating such as anodic bonding.

As long as an electronic component is of the type that can be housed in a housing portion by the cap member, various types of electronic components can be used. The frame-like member and the cap member can be formed of various materials.

What is claimed is:

1. An electronic component apparatus, comprising:
a wiring board;
an electronic component disposed on the wiring board;
a frame-like member that is provided on the wiring board to surround the electronic component and that has a ring-like bonding portion; and
a cap member bonded to the ring-like bonding portion of the frame-like member to constitute a housing portion for housing the electronic component, together with the wiring board and the frame-like member, wherein
in an upper part of one region of the ring-like bonding portion, one or more grooves for discharging air contained in the housing portion are provided to extend from an inner peripheral surface of the ring-like bonding portion to an outer side of the cap member.

2. The electronic component apparatus according to claim 1, wherein
the groove has a bent portion.

3. The electronic component apparatus according to claim 1, wherein
the cap member is bonded to the ring-like bonding portion by a thermoset adhesive agent formed on a region other than at least a part of the groove region in which the one or more grooves are provided.

4. The electronic component apparatus according to claim 1, wherein
the number of the grooves provided in the groove region is equal to or more than three.

5. The electronic component apparatus according to claim 1, wherein
the frame-like member includes a frame portion and the ring-like bonding portion that protrudes inwardly from an inner peripheral surface of the frame portion; and
the grooves are formed to extend from an inner peripheral surface of the ring-like bonding portion to an inner peripheral surface of the frame portion.

6. The electronic component apparatus according to claim 1, further comprising:
a lens module arranged on the frame-like member and the cap member, wherein
the electronic component apparatus is a camera module;
the electronic component is an image pickup element;
the cap member is formed of glass.

7. The electronic component apparatus according to claim 1, wherein
the electronic component is an optical semiconductor element or an MEMS element.
